(19) United States
(12) Patent Application Publication
(10) Pub. No.: US 2026/0068712 A1
(43) Pub. Date: Mar. 5, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Eitaro MIYAKE, Tachikawa Tokyo (JP)

(21) Appl. No.: 19/063,174

(22) Filed: Feb. 25, 2025

(30) Foreign Application Priority Data
Sep. 4, 2024 (JP) 2024-152499

(51) Int. Cl. H01L 23/498; H01L 23/13

(52) U.S. Cl. CPC H01L 23/49838

(57) ABSTRACT

A semiconductor device includes a substrate. The substrate has a first surface and a side surface. The semiconductor device has a plurality of electrodes on the first surface. The semiconductor device has a side surface cover that covers the side surface. The semiconductor device has a front surface cover. The first surface has an electrode-free portion covered with the front surface cover. The plurality of electrodes includes one or more electrode pairs, at least one of the one or more electrode pairs being disposed along an edge of the first surface. The side surface cover is connected to a portion between at least one electrode pair out of the front surface cover. A comparative tracking index of a material for forming the front surface cover and the side surface cover is greater than a comparative tracking index of a material for forming the substrate.

### CROSS-REFERENCE TO RELATED APPLICATION

This application is based upon and claims the benefit of priority from Japanese Patent Application No. 2024-152499, filed on Sep. 4, 2024, the entire content of which are incorporated herein by reference.

### FIELD

Embodiments described herein relate generally to a semiconductor device.

### BACKGROUND

In a semiconductor device, there is a need for securing a creepage distance (in the following description, simply referred to as a “creepage distance”) for avoiding an obstruction resulting from tracking between a plurality of electrodes formed on a substrate. For a solder resist that covers the front surface of a substrate, a lot of products composed of a material having a large comparative tracking index are commercially available. For this reason, the creepage distance between the electrodes on the front surface of the substrate is easily shortened. In contrast, a lot of substrates composed of a material having a comparative tracking index smaller than the comparative tracking index of the material of the solder resist are commercially available. For this reason, in a case where a plurality of electrodes are formed along an edge of the substrate, the creepage distance between the electrodes on a side surface of the substrate is difficult to shorten. Accordingly, since the interval between the electrodes is difficult to narrow, a reduction in size of the semiconductor device is difficult to achieve.

### BRIEF DESCRIPTION OF THE DRAWINGS

FIG. 1 is a cross-sectional view illustrating a semiconductor device of an embodiment.

FIG. 2 is a perspective view illustrating the semiconductor device of the embodiment.

FIG. 3 is a perspective view illustrating a part of the semiconductor device of the embodiment.

FIG. 4 is a first plan view illustrating a manufacturing process of the semiconductor device of the embodiment.

FIG. 5 is a second plan view illustrating a manufacturing process of the semiconductor device of the embodiment.

FIG. 6 is a third plan view illustrating a manufacturing process of the semiconductor device of the embodiment.

FIG. 7 is a perspective view illustrating a part of a semiconductor device of a first modification example of the embodiment.

FIG. 8 is a perspective view illustrating a part of a semiconductor device of a second modification example of the embodiment.

FIG. 9 is a perspective view illustrating a semiconductor device of a third modification example of the embodiment.

FIG. 10 is a perspective view illustrating a part of a semiconductor device of a fourth modification example of the embodiment.

### DETAILED DESCRIPTION

A semiconductor device of an embodiment includes a substrate of an insulator. The substrate has a first surface facing a first side in a plate thickness direction of the substrate. The substrate has a side surface intersecting the first surface out of an external surface of the substrate. The semiconductor device has a plurality of electrodes on the first surface. The semiconductor device has a side surface cover that covers at least a part of the side surface. The semiconductor device has a front surface cover. The first surface has an electrode-free portion where the plurality of electrodes is not present The electrode-free portion is covered with the front surface cover The plurality of electrodes includes one or more electrode pairs, at least one of the one or more electrode pairs being disposed along an edge of the first surface. The side surface cover is connected to a portion between at least one electrode pair out of the front surface cover. A comparative tracking index of each of a material for forming the front surface cover and a material for forming the side surface cover is greater than a comparative tracking index of a material for forming the substrate.

Hereinafter, the semiconductor device of the embodiment will be described with reference to the drawings.

A direction in which a Z axis illustrated in each drawing extends is a plate thickness direction of a substrate. A side (+Z side) to which an arrow in a Z-axis direction is pointed is a rear surface side of a semiconductor device. An opposite side (−Z side) to the side to which the arrow in the Z-axis direction is pointed is a front surface side of the semiconductor device. In the following description, the rear surface side of the semiconductor device is referred to as a “rear surface side” or “first side in the plate thickness direction”, the front surface side of the semiconductor device is referred to as a “front surface side” or “a second side in the plate thickness direction”, and the plate thickness direction of the substrate is simply referred to as a “plate thickness direction”.

A first direction D1 illustrated in each drawing is a direction perpendicular to the plate thickness direction. In the following description, a side (+D1 side) to which an arrow in the first direction D1 is pointed is referred to as “a first side in the first direction D1”, and an opposite side (−D1 side) to the side to which the arrow in the first direction D1 is pointed is referred to as “a second side in the first direction D1”.

A second direction D2 illustrated in each drawing is a direction perpendicular to both the plate thickness direction and the first direction D1. In the following description, a side (+D2 side) to which an arrow in the second direction D2 is pointed is referred to as “a first side in the second direction D2”, and an opposite side (−D2 side) to the side to which the arrow in the second direction D2 is pointed is referred to as “a second side in the second direction D2”.

### EMBODIMENT

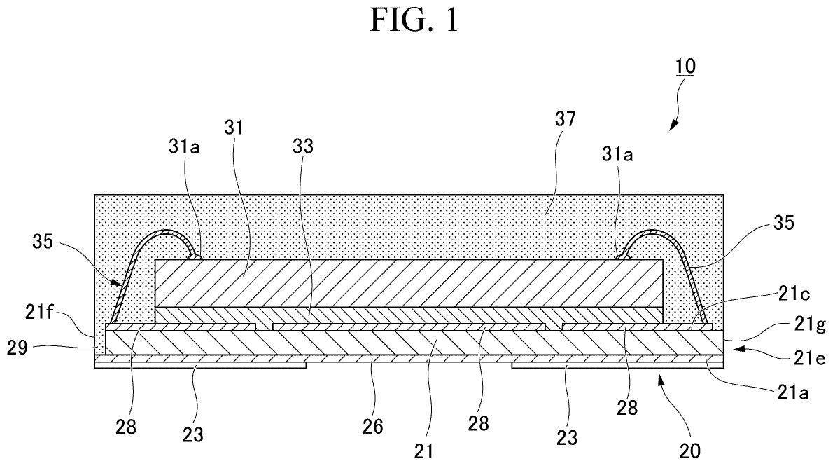

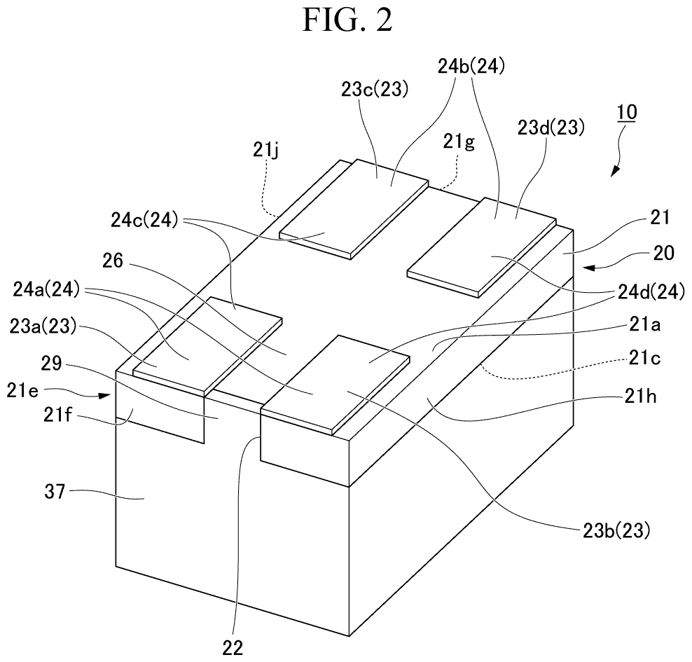

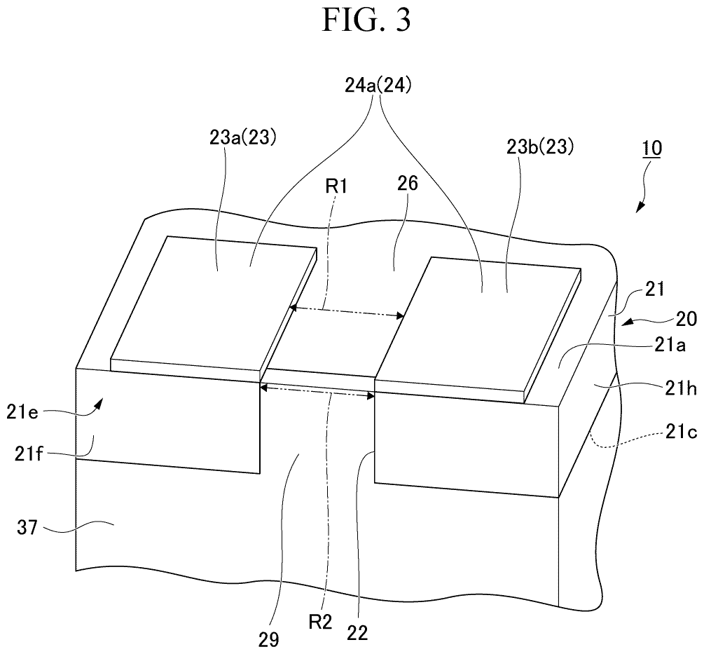

FIG. 1 is a cross-sectional view illustrating a semiconductor device 10 of the present embodiment. FIG. 2 is a perspective view illustrating the semiconductor device 10 of the present embodiment. FIG. 3 is a perspective view illustrating a part of the semiconductor device 10 of the present embodiment. The semiconductor device 10 of the present embodiment is, for example, a semiconductor device such as a metal oxide semiconductor field effect transistor (MOSFET), an insulated gate bipolar transistor (IGBT), or a photorelay. The semiconductor device 10 includes a substrate part 20, a chip 31, a bonding layer 33, wires 35, and a sealing part 37.

The substrate part 20 is a portion of the rear surface side (+Z side) of the semiconductor device 10. The substrate part 20 is electrically connected to an external power supply (not illustrated). The substrate part 20 supplies power supplied from the external power supply to the chip 31. The substrate part 20 outputs power converted by the chip 31 to an apparatus such as a motor. The substrate part 20 has a substrate 21, electrodes 23, a front surface cover 26, a wiring part 28, and a side surface cover 29. That is, the semiconductor device 10 includes the substrate 21, the electrodes 23, and the side surface cover 29.

The substrate 21 has a plate shape spreading in the direction perpendicular to the plate thickness direction. As illustrated in FIG. 2, when viewed from the plate thickness direction, the substrate 21 has a substantially rectangular shape in which a long side extends in the second direction D2. The substrate 21 of an insulator. The substrate 21 is a printed circuit board. In the present embodiment, a comparative tracking index (CTI) of a material for forming the substrate 21 is about 300. As illustrated in FIG. 1, the substrate 21 has a first surface 21a and a second surface 21c. As illustrated in FIG. 2, the substrate 21 has a side surface 21e.

A comparative tracking index of each part that configures the semiconductor device 10 of the present embodiment is measured on the basis of a tracking resistance test method (IEC 60112) set forth by the International Electrotechnical Commission. The comparative tracking index is an index indicating unlikelihood of tracking of an insulating material. With the use of a material having a large comparative tracking index, a creepage distance between electrodes 23 necessary for avoiding tracking can be shortened.

As illustrated in FIG. 1, the first surface 21a is a surface facing a rear surface side, that is, a first side in the plate thickness direction (+Z side) out of an external surface of the substrate 21. The second surface 21c is a surface facing a front surface side, that is, a second side in the plate thickness direction (−Z side) out of the external surface of the substrate 21. As illustrated in FIG. 2, the side surface 21e is a surface facing the direction perpendicular to the plate thickness direction out of the external surface of the substrate 21. The side surface 21e intersects each of the first surface 21a and the second surface 21c. In the present embodiment, the side surface 21e is perpendicular to each of the first surface 21a and the second surface 21c. The side surface 21e includes a first side surface 21f, a second side surface 21g, a third side surface 21h, and a fourth side surface 21j. In the present embodiment, a recess 22 is provided in the side surface 21e.

The first side surface 21f is a surface facing a first side in the second direction D2 (+D2 side). The second side surface 21g is a surface facing a second side in the second direction D2 (−D2 side). The third side surface 21h is a surface facing a first side in the first direction D1 (+D1 side). The fourth side surface 21j is a surface facing a second side in the first direction D1 (−D1 side).

The recess 22 is a depression that is depressed in the direction perpendicular to the plate thickness direction. In the present embodiment, the recess 22 is provided in the first side surface 21f. The recess 22 is depressed from the first side surface 21f to a second side in the second direction D2 (−D2 side). The recess 22 may be provided in any of the second side surface 21g, the third side surface 21h, and the fourth side surface 21j. In the present embodiment, the recess 22 is open to both sides of the rear surface side, that is, a first side in the plate thickness direction (+Z side) and the front surface side, that is, a second side in the plate thickness direction (−Z side). The recess 22 may not be open to the front surface side. In this case, the recess 22 is open only to the rear surface side. When viewed from the second direction D2, the recess 22 has a substantially rectangular shape. In the side surface 21e, the recess 22 may not be provided.

The electrodes 23 have a plate shape spreading in the direction perpendicular to the plate thickness direction. When viewed from the plate thickness direction, the electrodes 23 have a substantially rectangular shape in which a long side extends in the second direction D2. The electrodes 23 are on the first surface 21a of the substrate 21. In the present embodiment, the substrate part 20 has a plurality of electrodes 23. In the present embodiment, the substrate part 20 has four electrodes 23. The plurality of electrodes 23 includes a first electrode 23a, a second electrode 23b, a third electrode 23c, and a fourth electrode 23d.

According to the present embodiment, as described above, each of the plurality of electrodes 23 has a plate shape spreading in the direction perpendicular to the plate thickness direction. Accordingly, the dimension of each electrode 23 in the plate thickness direction is easily reduced. With this, it is possible to reduce the dimension of the semiconductor device 10 in the plate thickness direction. Therefore, a reduction in size of the semiconductor device 10 can be achieved.

The first electrode 23a and the second electrode 23b are disposed along an edge of the first surface 21a on a first side in the second direction D2 (+D2 side). The first electrode 23a and the second electrode 23b are disposed with an interval therebetween in the first direction D1. The first electrode 23a is disposed on a second side in the first direction D1 (−D1 side) with respect to the second electrode 23b. When viewed from the plate thickness direction, an end portion of each of the first electrode 23a and the second electrode 23b on a first side in the second direction D2 overlaps the edge of the first surface 21a on a first side in the second direction D2. The first electrode 23a is positioned on a second side in the first direction D1 with respect to the recess 22. In the present embodiment, when viewed from the plate thickness direction, an end portion of the recess 22 on the second side in the first direction D1 overlaps an end portion of the first electrode 23a on a first side in the first direction D1. The second electrode 23b is positioned on the first side in the first direction D1 with respect to the recess 22. When viewed from the plate thickness direction, an end portion of the recess 22 on the first side in the first direction D1 overlaps an end portion of the second electrode 23b on the second side in the first direction D1.

The third electrode 23c is disposed on the second side in the second direction D2 (−D2 side) with respect to the first electrode 23a. When viewed from the second direction D2, the third electrode 23c overlaps the first electrode 23a. When viewed from the plate thickness direction, an edge of the third electrode 23c on the second side in the second direction D2 overlaps an edge of the first surface 21a on the second side in the second direction D2.

The fourth electrode 23d is disposed on the second side in the second direction D2 (−D2 side) with respect to the second electrode 23b. When viewed from the second direction D2, the fourth electrode 23d overlaps the second electrode 23b. When viewed from the plate thickness direction, an edge of the fourth electrode 23d on the second side in the second direction D2 overlaps the edge of the first surface 21a on the second side in the second direction D2. The third electrode 23c and the fourth electrode 23d are disposed along the edge of the first surface 21a on the second side in the second direction D2. The third electrode 23c and the fourth electrode 23d are disposed with an interval therebetween in the first direction D1.

The first electrode 23a and the third electrode 23c are disposed along an edge of the first surface 21a on the second side in the first direction D1 (−D1 side). The first electrode 23a and the third electrode 23c are disposed with an interval therebetween in the second direction D2. The second electrode 23b and the fourth electrode 23d are disposed along an edge of the first surface 21a on a first side in the first direction D1 (+D1 side). The second electrode 23b and the fourth electrode 23d are disposed with an interval therebetween in the second direction D2.

The plurality of electrodes 23 includes electrode pairs 24, at least one of the one or more electrode pairs 24 being disposed along the edge of the first surface 21a. In the present embodiment, the plurality of electrodes 23 includes four electrode pairs 24. That is, the plurality of electrodes 23 includes one or more electrode pairs 24. The number of electrode pairs 24 included in the plurality of electrodes 23 may be three or less or may be five or more. A plurality of electrode pairs 24 includes a first electrode pair 24a, a second electrode pair 24b, a third electrode pair 24c, and a fourth electrode pair 24d.

The first electrode pair 24a has the first electrode 23a and the second electrode 23b. The second electrode pair 24b has the third electrode 23c and the fourth electrode 23d. The third electrode pair 24c has the first electrode 23a and the third electrode 23c. The fourth electrode pair 24d has the second electrode 23b and the fourth electrode 23d.

The first surface 21a has an electrode-free portion where the plurality of electrodes 23 is not present. The front surface cover 26 covers the electrode-free portion. That is, the electrode-free portion is covered with the front surface cover 26. The front surface cover 26 may cover a part of the portion where the plurality of electrodes 23 are not formed when viewed from the plate thickness direction, in the first surface 21a of the substrate 21. The front surface cover 26 has a film shape that covers the first surface 21a. The front surface cover 26 protects wiring (not illustrated) provided on the first surface 21a. In the present embodiment, the front surface cover 26 is composed of, for example, solder resist. A comparative tracking index of a material for forming the front surface cover 26, that is, a material for forming solder resist is equal to or greater than 600. The comparative tracking index of the material for forming the front surface cover 26 is greater than a comparative tracking index of a material for forming the substrate 21. With this, in each electrode pair 24, a creepage distance passing through the first surface 21a of the substrate 21 out of a creepage distance between a pair of electrodes 23 can be shortened.

As illustrated in FIG. 1, the wiring part 28 is a circuit pattern provided on the second surface 21c of the substrate 21. The wiring part 28 is made of metal. In the present embodiment, the wiring part 28 is made of copper. The wiring part 28 is electrically connected to each electrode 23 by a through-hole (not illustrated) or the like provided in the substrate 21.

The chip 31 is mounted on the second surface 21c of the substrate 21. In more detail, the chip 31 is fixed to the second surface 21c by the bonding layer 33. The bonding layer 33 is composed of solder or a sintered material of silver or the like. In the present embodiment, the bonding layer 33 is solder. The chip 31 includes, for example, a power element for power control. The chip 31 is composed of, for example, a semiconductor material such as silicon, silicon carbide, or gallium nitride. In the chip 31, a plurality of terminal portions 31a are provided.

Each of the plurality of terminal portions 31a is provided on a surface facing the front surface side (−Z side) of the chip 31. Each terminal portion 31a is made of metal. In the present embodiment, each terminal portion 31a is made of aluminum.

The wires 35 electrically connect the terminal portions 31a and the wiring part 28. The wires 35 are composed of metal such as aluminum or copper. In the present embodiment, the wire 35 is made of aluminum. The semiconductor device 10 includes a plurality of wires 35. One end of each wire 35 is bonded to the different terminal portion 31a. The other end of each wire 35 is bonded to the wiring part 28. With this, each wire 35 electrically connects the chip 31 and the wiring part 28.

The sealing part 37 covers each of the second surface 21c of the substrate 21, the wiring part 28, the chip 31, and each wire 35. As illustrated in FIG. 2, the sealing part 37 has a substantially rectangular parallelepiped shape protruding in the plate thickness direction. When viewed from the plate thickness direction, the sealing part 37 has a substantially rectangular shape in which a long side extends in the second direction D2. The sealing part 37 is composed of resin of an insulator. The sealing part 37 is composed of, for example, resin primarily containing epoxy resin, bismaleimide resin, or cyanate resin. In the present embodiment, the sealing part 37 is composed of epoxy resin. The sealing part 37 protects each of the wiring part 28, the chip 31, and each wire 35. Therefore, according to the present embodiment, it is possible to increase the stability of the operation of the semiconductor device 10 by the sealing part 37.

As illustrated in FIG. 2, the side surface cover 29 is disposed between the first electrode 23a and the second electrode 23b of the first electrode pair 24a in the first direction D1. In the present embodiment, the side surface cover 29 is disposed inside the recess 22. An end portion of the side surface cover 29 on the rear surface side (+Z side) is connected to a portion between the first electrode pair 24a out of the front surface cover 26. That is, the side surface cover 29 is connected to a portion between at least one electrode pair 24 out of the front surface cover 26. An end portion of the side surface cover 29 on the front surface side (−Z side) is connected to the sealing part 37. In the present embodiment, the side surface cover 29 is a part of the sealing part 37. In the present embodiment, the side surface cover 29 is made of epoxy resin. The side surface cover 29 may be composed of other kinds of resin such as bismaleimide resin or cyanate resin. A comparative tracking index of a material for forming the side surface cover 29 is equal to or greater than 600. The comparative tracking index of the material for forming the side surface cover 29 is greater than the comparative tracking index of the material for forming the substrate 21. With this, it is possible to shorten a creepage distance passing through the first side surface 21f out of the creepage distance between a pair of electrodes 23 in the first electrode pair 24a compared to a configuration in which the side surface cover 29 is not disposed in the recess 22.

Though not illustrated, in a case where the recess 22 is not open to the front surface side (−Z side), the side surface cover 29 may not be connected to the sealing part 37. In this case, the side surface cover 29 and the sealing part 37 are separate members.

Though not illustrated, in a case where the recess 22 is not provided in the first side surface 21f, the side surface cover 29 is provided on the first side surface 21f. Also in this case, the end portion of the side surface cover 29 on the rear surface side (+Z side) is connected to the portion between the first electrode pair 24a out of the front surface cover 26. Accordingly, it is possible to shorten the creepage distance passing through the first side surface 21f out of the creepage distance between a pair of electrodes 23 in the first electrode pair 24a. The end portion of the side surface cover 29 on the front surface side (−Z side) may be connected to the sealing part 37 or may not be connected to the sealing part 37. That is, the side surface cover 29 may be a part of the sealing part 37 or may be a member separate from the sealing part 37.

According to the present embodiment, the recess 22 that is depressed in the direction perpendicular to the plate thickness direction and is open to the rear surface side, that is, a first side in the plate thickness direction (+Z side) is provided in the side surface 21e, and the side surface cover 29 is disposed inside the recess 22. Accordingly, compared to a case where the recess 22 is not provided in the side surface 21e, and the side surface cover 29 is provided on the first side surface 21f, it is possible to suppress an increase in dimension of the semiconductor device 10 in the second direction D2. Therefore, reduction in size of the semiconductor device 10 can be more suitably achieved.

In a case where members such as the plurality of electrodes 23 to which a voltage is applied are on the substrate 21, it is necessary to make an interval between a pair of electrodes 23 of the electrode pair 24 wider than the creepage distance for avoiding an obstruction resulting from tracking. The creepage distance in each electrode pair 24 is determined by a potential difference that is a difference between potentials applied to the pair of electrodes 23, and a comparative tracking index of the surface of the substrate 21 between the pair of electrodes 23. In the first electrode pair 24a illustrated in FIG. 3, a route where tracking may occur includes a first route R1 passing through the first surface 21a of the substrate 21 and a second route R2 passing through the first side surface 21f of the substrate 21. As described above, the front surface cover 26 covers the first surface 21a. The comparative tracking index of the material for forming the front surface cover 26 is greater than the comparative tracking index of the material for forming the substrate 21. For this reason, in the present embodiment, it is possible to shorten a first creepage distance in the first route R1 passing through the first surface 21a of the substrate 21.

For solder resist for forming the front surface cover 26, a lot of products composed of a material having a large comparative tracking index are distributed. In contrast, a lot of substrates 21 composed of a material having a comparative tracking index smaller than the comparative tracking index of solder resist are distributed. For this reason, as in the present embodiment, in a case where the substrate 21 having a small comparative tracking index is used, if the plurality of electrodes 23 are formed along the edge of the substrate 21, a second creepage distance in the second route R2 passing through the side surface 21e of the substrate 21 is likely to be longer than the first creepage distance. In contrast, in the present embodiment, as described above, the comparative tracking index of the material for forming the side surface cover 29 is greater than the comparative tracking index of the material for forming the substrate 21. The side surface cover 29 is connected to the portion between the first electrode pair 24a out of the front surface cover 26. For this reason, in the present embodiment, it is possible to shorten the second creepage distance in the second route R2 by the side surface cover 29. As described above, in the present embodiment, it is possible to shorten the first creepage distance in the first route R1. With this, in the present embodiment, the interval between the first electrode 23a and the second electrode 23b of the first electrode pair 24a can be narrowed.

In the present embodiment, a potential difference between a pair of electrodes 23 of each of the second electrode pair 24b, the third electrode pair 24c, and the fourth electrode pair 24d is smaller than the potential difference between the pair of electrodes 23 of the first electrode pair 24a. For this reason, in the present embodiment, even when the side surface cover 29 is not provided on each of the second side surface 21g, the third side surface 21h, and the fourth side surface 21j of the substrate 21, it is possible to secure the creepage distance between the pair of electrodes 23 of each of the second electrode pair 24b, the third electrode pair 24c, and the fourth electrode pair 24d. In a case where the second electrode pair 24b, the third electrode pair 24c, and the fourth electrode pair 24d have a large potential difference, the side surface cover is suitably provided on the second side surface 21g, the third side surface 21h, and the fourth side surface 21j, so that it is possible to shorten the second creepage distance in the second route passing through the side surface 21e of the substrate 21. With this, it is possible to prevent an increase in interval between the pair of electrodes 23.

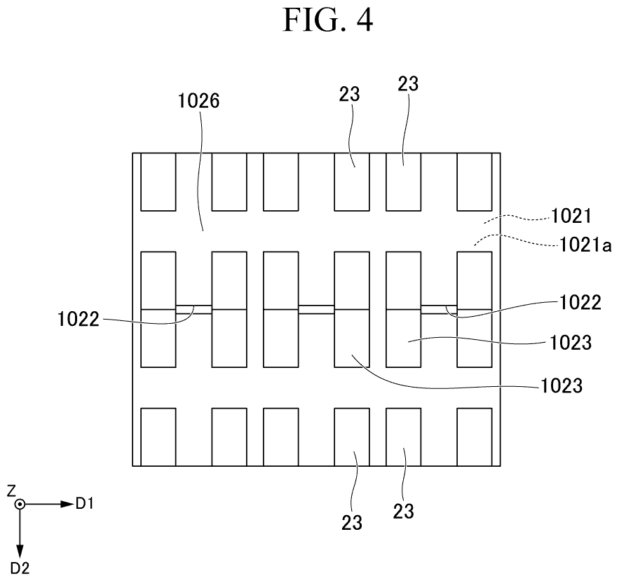

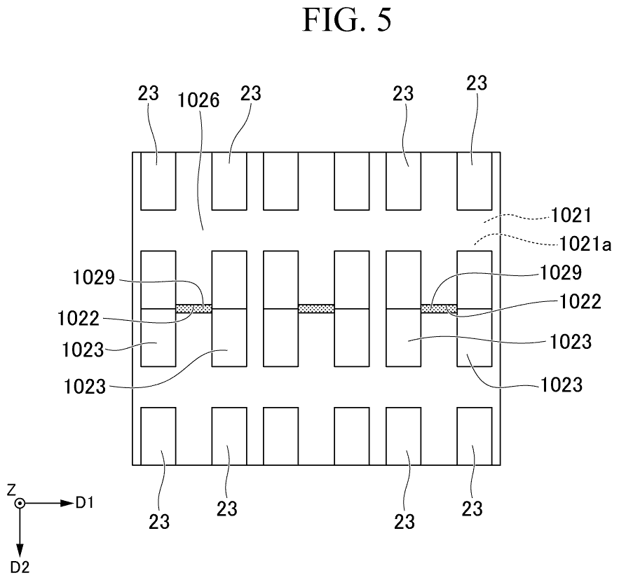

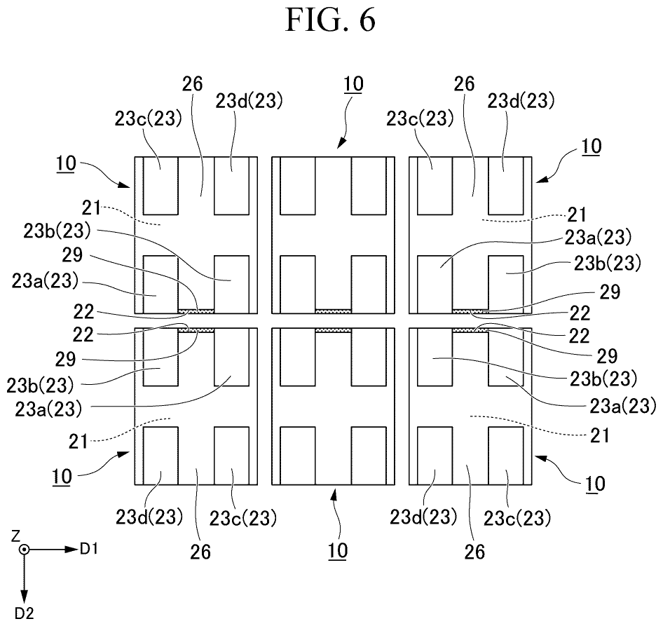

FIG. 4 is a first plan view illustrating a manufacturing process of the semiconductor device 10 of the present embodiment. FIG. 5 is a second plan view illustrating a manufacturing process of the semiconductor device 10 of the present embodiment. FIG. 6 is a third plan view illustrating the manufacturing process of the semiconductor device 10 of the present embodiment. Next, a manufacturing process of the semiconductor device 10 of the present embodiment will be described. The manufacturing process of the semiconductor device 10 includes a boring step P01, a sealing part forming step P02, and a dicing step P03. In the following description, a “worker or the like” includes a worker, an assembling device, or the like that performs work of each step. The work of each step may be performed only by the worker, may be performed only by the assembling device, or may be performed by the worker and the assembling device.

The boring step P01 is a step of boring through-holes 1022 in a base substrate 1021. In the present embodiment, the base substrate 1021 illustrated in FIG. 4 is a substrate in which six substrates 21 are connected, An area of the base substrate 1021 is about six times greater than an area of the substrate 21. The base substrate 1021 may be a substrate in which five or less substrates 21 are connected or may be a substrate in which seven or more substrates 21 are connected. When viewed from the plate thickness direction, the base substrate 1021 has a substantially rectangular shaped in which a long side extends in the first direction D1. Though not illustrated, the worker or the like mounts a plurality of chips 31 on a second surface of the base substrate 1021, and then, bonds wires 35 to the terminal portions 31a and the wiring part 28 of each chip 31. Next, the worker or the like forms a plurality of electrodes 23 and 1023 on a first surface 1021a of the base substrate 1021. In each of an edge of the base substrate 1021 on a first side in the second direction D2 (+D2 side) and an edge of the base substrate 1021 on a second side in the second direction D2 (−D2 side), a dimension of each of the electrodes 23 formed along the first direction D1 is the same as a dimension of the electrode 23 of the semiconductor device 10. In a central portion of the base substrate 1021 in the second direction D2, a dimension in the first direction D1 of each of the electrodes 1023 formed along the first direction D1 is the same dimension as the dimension in the first direction D1 of the electrode 23, and a dimension in the second direction D2 of each electrode 1023 is about two times greater than the dimension in the second direction D2 of the electrode 23.

Next, the worker or the like applies a front surface cover 1026 in a portion out of the first surface 1021a where the plurality of electrodes 23 and 1023 are not formed when viewed from the plate thickness direction. With this, an electrode-free portion is covered with the front surface cover 1026. Next, the worker or the like bores the through-hole 1022 between a pair of electrodes 1023. The through-hole 1022 is a hole that passes through the base substrate 1021 in the plate thickness direction. When viewed from the plate thickness direction, the through-hole 1022 has a substantially rectangular shape in which a long side extends in the second direction D2. The through-hole 1022 is open to both sides of the rear surface side, that is, a first side in the plate thickness direction (+Z side) and the front surface side, that is, a second side in the plate thickness direction (−Z side), of the base substrate 1021. In the present embodiment, the worker or the like bores three through-holes 1022. If the worker or the like bores each through-hole 1022, the boring step P01 ends.

The sealing part forming step P02 is a step of forming each of the sealing part 37 (see FIG. 1) and a side surface cover 1029. Though not illustrated, the worker or the like fills epoxy resin from the front surface side (−Z side) of the base substrate 1021. With this, each of the plurality of chips 31 and wires 35 mounted on the second surface of the base substrate 1021 is covered with the sealing part 37 (see FIG. 1). As described above, the through-holes 1022 are open to the front surface side of the base substrate 1021. For this reason, as illustrated in FIG. 5, a part of epoxy resin flows into each through-hole 1022, and the inside of each through-hole 1022 is filled with the side surface cover 1029. With this, though not illustrated, an end portion of the side surface cover 1029 on the front surface side is connected to the sealing part 37. That is, the side surface cover 1029 is connected to the sealing part 37. Next, the worker or the like cures each of the sealing part 37 and the side surface cover 1029 by heating each of the sealing part 37 and the side surface cover 1029 in a furnace or the like. If the worker or the like cures each of the sealing part 37 and the side surface cover 1029, the sealing part forming step P02 ends.

The dicing step P03 is a step of dividing and dicing the base substrate 1021 into a plurality of semiconductor devices 10. As illustrated in FIG. 6, the worker or the like dices the base substrate 1021 into six semiconductor devices 10 by cutting the base substrate 1021, each electrode 1023, each through-hole 1022, and each side surface cover 1029. The worker or the like cuts the base substrate 1021 and the like by a dicing device (not illustrated) having a blade. The worker or the like may cut the base substrate 1021 and the like by other devices such as a laser dicing device. Each cut electrode 1023 configures the first electrode 23a and the second electrode 23b in each semiconductor device 10. Each cut through-hole 1022 configures the recess 22 in each semiconductor device 10. Each cut side surface cover 1029 configures the side surface cover 29 in each semiconductor device 10. If the worker or the like dices each semiconductor device 10, the dicing step P03 ends. If the dicing step P03 ends, the manufacturing process of the semiconductor device 10 ends.

Though not illustrated, as described above, in a case where the recess 22 is not open to the front surface side (−Z side), the side surface cover 29 and the sealing part 37 are separate members. In this case, the worker or the like can form the side surface cover 29 inside each recess 22 by filling the inside of each recess 22 with the side surface cover 29 after the dicing step P03 ends.

According to the present embodiment, the semiconductor device 10 includes the sealing part 37 that covers the second surface 21c facing the front surface side of the substrate 21, that is, the second side in the plate thickness direction (−Z side), the recess 22 is open to the front surface side, and the side surface cover 29 is connected to the sealing part 37. Accordingly, as described above, in the sealing part forming step P02, in filling the second surface of the base substrate 1021 with resin for forming the sealing part 37, the inside of each through-hole 1022 can be filled with the side surface cover 1029. That is, in the sealing part forming step P02, each of the sealing part 37 and the side surface cover 29 can be formed by the same filling work. Accordingly, it is possible to suppress an increase in manufacturing man-hours of the semiconductor device 10 compared to a case where each of the sealing part 37 and the side surface cover 29 is formed by different filling work.

According to the present embodiment, the semiconductor device 10 includes the substrate 21 of an insulator, the plurality of electrodes 23 on the first surface 21a facing the rear surface side of the substrate 21, that is, a first side in the plate thickness direction (+Z side), and the side surface cover 29 that covers at least a part of the side surface 21e intersecting the first surface 21a out of the external surface of the substrate 21. The portion out of the first surface 21a where the plurality of electrodes 23 are not formed when viewed from the plate thickness direction is covered with the front surface cover 26, the plurality of electrodes 23 includes one or more electrode pairs 24 each composed of a pair of electrodes 23 disposed along the edge of the first surface 21a, and the side surface cover 29 is connected to the portion between at least one electrode pair 24 out of the front surface cover 26. The comparative tracking index of each of the material for forming the front surface cover 26 and the material for forming the side surface cover 29 is greater than the comparative tracking index of the material for forming the substrate 21. For this reason, in a direction in which a pair of electrodes 23a and 23b of the electrode pair 24 is disposed, in the present embodiment, the first direction D1, the side surface cover 29 is disposed between a pair of electrodes 23a and 23b, and the end portion of the side surface cover 29 on the rear surface side is connected to the front surface cover 26. With this, as described above, compared to a case where the side surface cover 29 is not provided in the first side surface 21f, it is possible to shorten the second creepage distance in the second route R2 passing through the first side surface 21f of the substrate 21 out of the creepage distance between the pair of electrodes 23a and 23b. Therefore, since the interval between the pair of electrodes 23a and 23b of the electrode pair 24 can be narrowed, reduction in size of the semiconductor device 10 can be suitably achieved.

In the present embodiment, as described above, since it is possible to shorten the second creepage distance between the pair of electrodes 23a and 23b by the side surface cover 29, it is possible to prevent the interval between the pair of electrodes 23a and 23b from being determined on the basis of the comparative tracking index of the material for forming the substrate 21. With this, since it is possible to prevent a restriction to the choice of the material for forming the substrate 21, the manufacturing cost of the substrate 21 is easily reduced. Therefore, it is possible to suppress an increase in manufacturing cost of the semiconductor device 10.

In the present embodiment, as described above, an electrode-free portion is covered with the front surface cover 26. With this, it is possible to shorten the first creepage distance in the first route R1 passing through the first surface 21a of the substrate 21 out of the creepage distance in the pair of electrodes 23a and 23b. Therefore, since the interval between the pair of electrodes 23a and 23b can be more suitably narrowed, reduction in size of the semiconductor device 10 can be more suitably achieved.

### First Modification Example

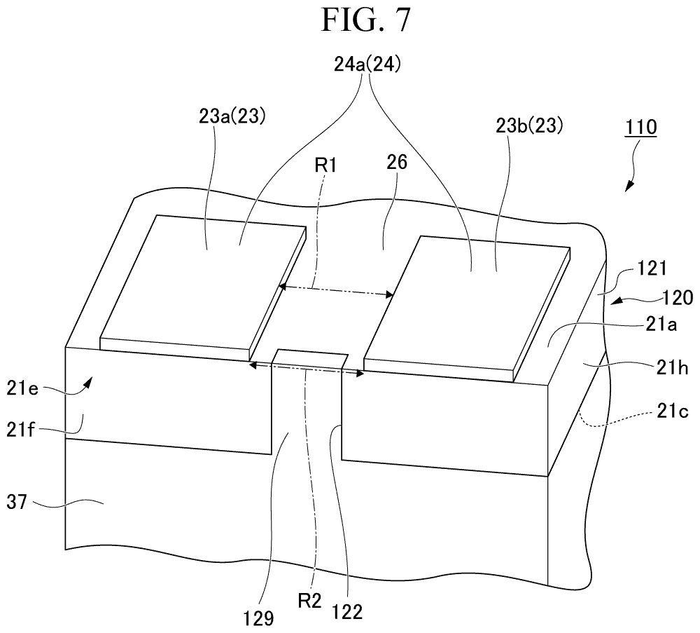

FIG. 7 is a perspective view illustrating a part of a semiconductor device 110 of the present modification example. In the semiconductor device 110 of the present modification example, each of a dimension of a recess 122 in the first direction D1 and a dimension of a side surface cover 129 in the first direction D1 is smaller than an interval between the first electrode 23a and the second electrode 23b in the first direction D1. In the following description, the same components as those in the above-described embodiment are given the same reference numerals, and description thereof will not be repeated.

As illustrated in FIG. 7, the recess 122 of the present modification example is a depression that is depressed in a direction perpendicular to the plate thickness direction. The recess 122 is depressed from the first side surface 21f to a second side in the second direction D2 (−D2 side). In the present modification example, the recess 122 is open to both sides of the rear surface side (+Z side) and the front surface side (−Z side). As described above, in the present modification example, the dimension of the recess 122 in the first direction D1 is smaller than the interval between the first electrode 23a and the second electrode 23b in the first direction D1. In the present modification example, an end portion of the recess 122 on a second side in the first direction D1 (−D1 side) is positioned on a first side in the first direction D1 (+D1 side) with respect to the first electrode 23a. An end portion of the recess 122 on a first side in the first direction D1 is positioned on a second side in the first direction D1 with respect to the second electrode 23b. Other configurations and the like of a substrate 121 in a substrate part 120 of the present modification example are similar to other configurations and the like of the substrate 21 in the substrate part 20 of the above-described embodiment.

The side surface cover 129 is disposed between the first electrode 23a and the second electrode 23b of the first electrode pair 24a in the first direction D1. The side surface cover 129 is disposed inside the recess 122. An end portion of the side surface cover 129 on the rear surface side (+Z side) is connected to a portion between the first electrode pair 24a out of the front surface cover 26. That is, the side surface cover 129 is connected to the portion between at least one electrode pair 24 out of the front surface cover 26. An end portion of the side surface cover 129 on the front surface side (−Z side) is connected to the sealing part 37. A comparative tracking index of a material for forming the side surface cover 129 is greater than a comparative tracking index of a material for forming the substrate 121. Other configurations and the like of the side surface cover 129 of the present modification example are similar to other configurations and the like of the side surface cover 29 of the above-described embodiment. Other configurations and the like of the semiconductor device 110 of the present modification example are similar to other configurations and the like of the semiconductor device 10 of the above-described embodiment.

According to the present modification example, the side surface cover 129 is connected to the portion between at least one electrode pair 24 out of the front surface cover 26, and the comparative tracking index of each of the material for forming the front surface cover 26 and the material for forming the side surface cover 129 is greater than the comparative tracking index of the material for forming the substrate 121. For this reason, similarly to the above-described embodiment, it is possible to shorten the second creepage distance in the second route R2 passing through the first side surface 21f of the substrate 121 out of the creepage distance between a pair of electrodes 23a and 23b compared to a case where the side surface cover 129 is not provided in the first side surface 21f. Therefore, since the interval between the pair of electrodes 23a and 23b of the electrode pair 24 can be narrowed, reduction in size of the semiconductor device 110 can be more suitably achieved.

In the present modification example, as described above, the dimension of the recess 122 in the first direction D1 is smaller than the interval between the first electrode 23a and the second electrode 23b in the first direction D1. For this reason, in the boring step P01, it is possible to reduce the dimension of each through-hole 1022 that is formed in the base substrate 1021. With this, since it is possible to prevent an increase in work man-hours for boring in the base substrate 1021, the manufacturing cost of the substrate 121 can be reduced. Therefore, it is possible to suppress an increase in manufacturing cost of the semiconductor device 110.

In the present modification example, as described above, the dimension of the side surface cover 129 in the first direction D1 is smaller than the interval between the first electrode 23a and the second electrode 23b in the first direction D1. With this, since the volume of the side surface cover 129 is easily reduced, the manufacturing cost of the side surface cover 129 can be reduced. Therefore, it is possible to more suitably suppress an increase in manufacturing cost of the semiconductor device 110.

### Second Modification Example

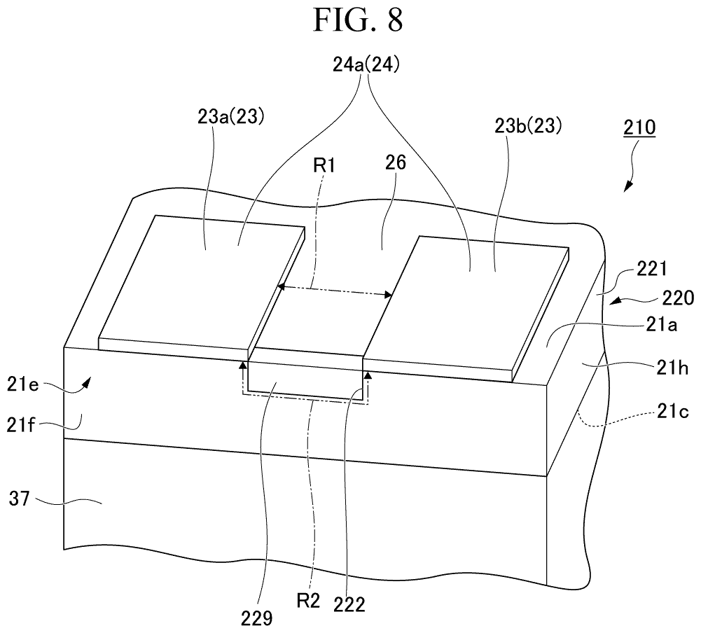

FIG. 8 is a perspective view illustrating a part of a semiconductor device 210 of the present modification example. In the semiconductor device 210 of the present modification example, the recess 222 is not open to the front surface side (−Z side). That is, a dimension of the recess 222 in the plate thickness direction is smaller than a dimension of a substrate 221 in the plate thickness direction. In the following description, the same components as those in the above-described embodiment are given the same reference numerals, and description thereof will not be repeated.

As illustrated in FIG. 8, the recess 222 of the present modification example is a depression that is depressed in a direction perpendicular to the plate thickness direction. The recess 222 is depressed from the first side surface 21f to the second side in the second direction D2 (−D2 side). In the present modification example, the recess 222 is open only to the rear surface side (+Z side), and is not open to the front surface side (−Z side). Other configurations and the like of a substrate 221 in a substrate part 220 of the present modification example are similar to other configurations and the like of the substrate 21 in the substrate part 20 of the above-described embodiment.

A side surface cover 229 of the present modification example is disposed between the first electrode 23a and the second electrode 23b of the first electrode pair 24a in the first direction D1. The side surface cover 229 is disposed inside the recess 222. An end portion of the side surface cover 229 on the rear surface side (+Z side) is connected to the portion between the first electrode pair 24a out of the front surface cover 26. That is, the side surface cover 229 is connected to the portion between at least one electrode pair 24 out of the front surface cover 26. An end portion of the side surface cover 229 on the front surface side (−Z side) is not connected to the sealing part 37. The end portion of the side surface cover 229 on the front surface side in the present modification example is positioned on the front surface side with respect to the first surface 21a and on the rear surface side with respect to the second surface 21c. A dimension of the side surface cover 229 in the plate thickness direction is smaller than a dimension of the substrate 221 in the plate thickness direction. A comparative tracking index of a material for forming the side surface cover 229 is greater than a comparative tracking index of a material for forming the substrate 221. Other configurations and the like of the side surface cover 229 of the present modification example are similar to other configurations and the like of the side surface cover 29 of the above-described embodiment. Other configurations and the like of the semiconductor device 210 of the present modification example are similar to other configurations and the like of the semiconductor device 10 of the above-described embodiment.

According to the present modification example, the side surface cover 229 is connected to the portion between at least one electrode pair 24 out of the front surface cover 26, the end portion of the side surface cover 229 on the front surface side (−Z side) is positioned on the front surface side with respect to the first surface 21a and on the rear surface side (+Z side) with respect to the second surface 21c, and the comparative tracking index of each of the material for forming the front surface cover 26 and the material for forming the side surface cover 229 is greater than the comparative tracking index of the material for forming the substrate 221. For this reason, the second route R2 passing through the first side surface 21f of the substrate 221 out of the creepage distance between a pair of electrodes 23a and 23b becomes a route that bypasses the front surface side with respect to the side surface cover 229 along the outer periphery of the side surface cover 229. With this, it is possible to make the second route R2 longer than the interval between the pair of electrodes 23a and 23b in the first direction D1 compared to a case where the side surface cover 229 is not provided in the first side surface 21f. With this, even when the interval between the pair of electrodes 23a and 23b in the first direction D1 is narrowed, the creepage distance between the pair of electrodes 23a and 23b is easily secured. Thus, reduction in size of the semiconductor device 210 can be achieved.

In the present modification example, as described above, the recess 222 is not open to the front surface side (−Z side). Accordingly, as described above, the dimension of the recess 222 in the plate thickness direction is smaller than the dimension of the substrate 221 in the plate thickness direction. For this reason, in the boring step P01, it is possible to reduce a dimension in the plate thickness direction of each through-hole 1022 formed in the base substrate 1021. With this, since it is possible to suppress an increase in work man-hours for boring in the base substrate 1021, it is possible to reduce the manufacturing cost of the substrate 221. Therefore, it is possible to suppress an increase in manufacturing cost of the semiconductor device 210.

In the present modification example, as described above, the dimension of the side surface cover 229 in the plate thickness direction is smaller than the dimension of the substrate 221 in the plate thickness direction. With this, since the volume of the side surface cover 229 is easily reduced, it is possible to reduce the manufacturing cost of the side surface cover 229. Therefore, it is possible to more suitably suppress an increase in manufacturing cost of the semiconductor device 210.

### Third Modification Example

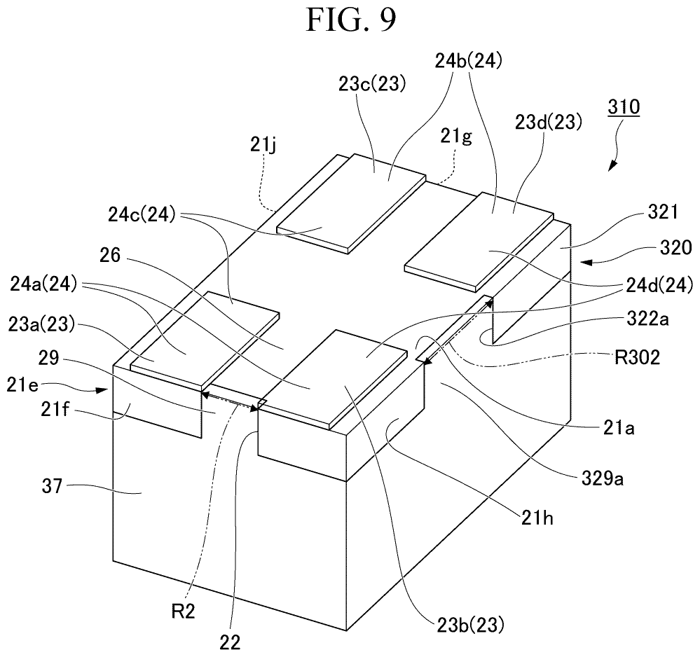

FIG. 9 is a perspective view illustrating a semiconductor device 310 of the present modification example. The semiconductor device 310 of the present modification example includes a plurality of side surface covers 29 and 329a. In the following description, the same components as those in the above-described embodiment are given the same reference numerals, and a description thereof will not be repeated.

As illustrated in FIG. 9, in the present modification example, a plurality of recesses 22 and 322a are provided in the side surface 21e. The configuration and the like of the recess 22 of the present modification example are similar to the configuration and the like of the recess 22 of the above-described embodiment.

The recess 322a is a depression that is depressed in a direction perpendicular to the plate thickness direction. The recess 322a is depressed from the third side surface 21h to a second side in the first direction D1 (−D1 side). When viewed from the first direction D1, the recess 322a has a substantially rectangular shape in which a long side extends in the second direction D2. In the present modification example, the recess 322a is open to both sides of the rear surface side (+Z side) and the front surface side (−Z side). In the second direction D2, the recess 322a is disposed between the second electrode 23b and the fourth electrode 23d. That is, the recess 322a is disposed on a second side in the second direction D2 (−D2 side) with respect to the second electrode 23b, and is disposed on a first side in the second direction D2 (+D2 side) with respect to the fourth electrode 23d. An end portion of the recess 322a on a first side in the second direction D2 may be positioned on the first side in the second direction D2 with respect to an end portion of the second electrode 23b on the second side in the second direction D2. An end portion of the recess 322a on the second side in the second direction D2 may be positioned on the second side in the second direction D2 with respect to an end portion of the fourth electrode 23d on the first side in the second direction D2. Other configurations and the like of a substrate 321 in a substrate part 320 of the present modification example are similar to other configurations and the like of the substrate 21 in the substrate part 20 of the above-described embodiment.

In the present modification example, the semiconductor device 310 includes a plurality of side surface covers 29 and 329a. The semiconductor device 310 includes two side surface covers 29 and 329a. The configuration and the like of the side surface cover 29 of the present modification example are similar to the configuration and the like of the side surface cover 29 of the above-described embodiment.

The side surface cover 329a is disposed inside the recess 322a. The side surface cover 329a is disposed between the second electrode 23b and the fourth electrode 23d of the fourth electrode pair 24d in the second direction D2. An end portion of the side surface cover 329a on the rear surface side (+Z side) is connected to a portion between the fourth electrode pair 24d out of the front surface cover 26. That is, the side surface cover 329a is connected to a portion between at least one electrode pair 24 out of the front surface cover 26. With this, each of the plurality of side surface covers 29 and 329a are connected to a portion between a different electrode pair 24 out of the front surface cover 26. In the present modification example, an end portion of the side surface cover 329a on the front surface side (−Z side) is connected to the sealing part 37. The side surface cover 329a is a part of the sealing part 37. A comparative tracking index of a material for forming each of the side surface covers 29 and 329a is greater than a comparative tracking index of a material for forming the substrate 321. Other configurations and the like of each of the side surface covers 29 and 329a of the present modification example are similar to other configurations and the like of the side surface cover 29 of the above-described embodiment. Other configurations and the like of the semiconductor device 310 of the present modification example are similar to other configurations of the semiconductor device 10 of the above-described embodiment.

In the present modification example, a potential difference between a pair of electrodes 23 of each of the first electrode pair 24a and the fourth electrode pair 24d is greater than a potential difference between a pair of electrodes 23 of each of the second electrode pair 24b and the third electrode pair 24c. For this reason, in the present modification example, the side surface cover 29 is provided in the first side surface 21f of the substrate 321, so that it is possible to shorten the second creepage distance in the second router R2 passing through the first side surface 21f of the substrate 321 out of the creepage distance between a pair of electrodes 23a and 23b similarly to the above-described embodiment. In the present modification example, the side surface cover 329a is provided in the third side surface 21h of the substrate 321, so that it is possible to shorten the second creepage distance in the second route R302 passing through the third side surface 21h of the substrate 321 out of the creepage distance between a pair of electrodes 23b and 23d. With this, each of an interval between the pair of electrodes 23a and 23b and an interval between the pair of electrodes 23b and 23d can be narrowed. According to the present modification example, the semiconductor device 310 includes the plurality of side surface covers 29 and 329a, the plurality of electrodes 23 includes the plurality of electrode pairs 24, and each of the plurality of side surface covers 29 and 329a is connected to the portion between a different electrode pair 24 out of the front surface cover 26. For this reason, as described above, even when each of the interval between the pair of electrodes 23a and 23b and the interval between the pair of electrodes 23b and 23d is narrowed, it is possible to secure each of the creepage distance between the pair of electrodes 23a and 23b and the creepage distance between the pair of electrodes 23b and 23d. Thus, a reduction in size of the semiconductor device 310 can be achieved.

### Fourth Modification Example

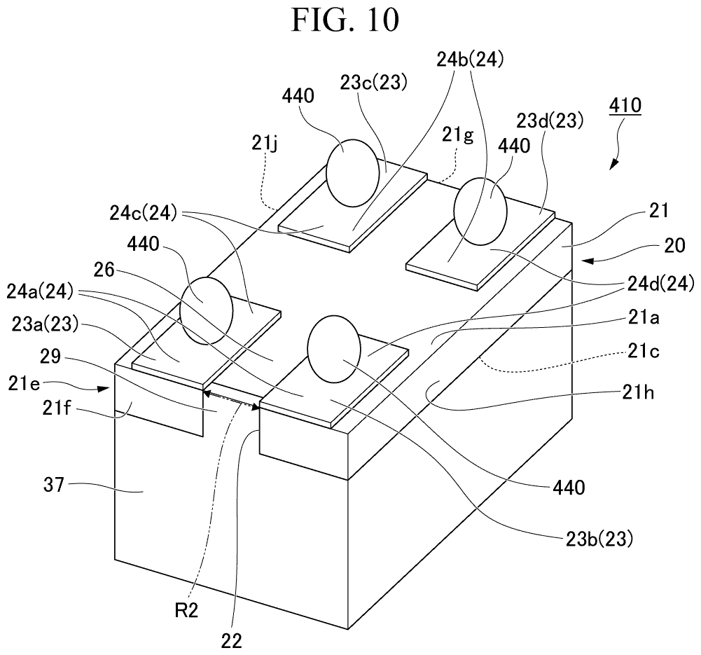

FIG. 10 is a perspective view illustrating a semiconductor device 410 of the present modification example. In the semiconductor device 410 of the present modification example, a solder ball 440 is mounted on each of a plurality of electrodes 23. In the following description, the same components as those in the above-described embodiment are given the same reference numerals, and a description thereof will not be repeated.

As illustrated in FIG. 10, in the present modification example, the solder ball 440 is mounted on each of the plurality of electrodes 23. Each solder ball 440 has conductivity. In the present embodiment, each solder ball 440 is composed of a metal material such as copper, silver, or tin. Each solder ball 440 is heated and welded along with an external terminal of an external power supply (not illustrated), so that each electrode 23 and the external terminal are closely attached and fixed via the solder ball 440. With this, it is possible to stabilize electrical connection of each electrode 23 and the external terminal. Therefore, it is possible to increase the stability of the operation of the semiconductor device 410.

In the present modification example, similarly to the above-described embodiment, the side surface cover 29 is connected to a portion between at least one electrode pair 24 out of the front surface cover 26, and the comparative tracking index of each of the material for forming the front surface cover 26 and the material for forming the side surface cover 29 is greater than the comparative tracking index of the material for forming the substrate 21. For this reason, it is possible to shorten the second creepage distance in the second route R2 passing through the first side surface 21f of the substrate 21 out of the creepage distance between a pair of electrodes 23a and 23b. Therefore, since the interval between a pair of electrodes 23a and 23b of the electrode pair 24 can be narrowed, a reduction in size of the semiconductor device 10 can be suitably achieved.

According to at least one embodiment described above, the side surface cover that is connected to the portion between at least one electrode pair out of the front surface cover and has the comparative tracking index greater than the comparative tracking index of the material for forming the substrate is provided, so that it is possible to provide a semiconductor device capable of achieving reduction in size.

While certain embodiments have been described, these embodiments have been presented as exemplary examples only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate of an insulator, the substrate having a first surface facing a first side in a plate thickness direction of the substrate, the substrate having a side surface intersecting the first surface out of an external surface of the substrate; and
a plurality of electrodes on the first surface; and
a side surface cover that covers at least a part of the side surface; and
a front surface cover;
wherein the first surface having an electrode-free portion where the plurality of electrodes is not present, the electrode-free portion is covered with the front surface cover,
the plurality of electrodes includes one or more electrode pairs, at least one of the one or more electrode pairs being disposed along an edge of the first surface,
the side surface cover is connected to a portion between at least one electrode pair out of the front cover, and
a comparative tracking index of each of a material for forming the front surface cover and a material for forming the side surface cover is greater than a comparative tracking index of a material for forming the substrate.

2. The semiconductor device according to claim 1,
wherein a recess that is depressed in a direction perpendicular to the plate thickness direction and is open to the first side in the plate thickness direction is provided in the side surface, and
the side surface cover is disposed inside the recess.

3. The semiconductor device according to claim 2, further comprising:
a sealing part that covers a second surface facing a second side in the plate thickness direction of the substrate,
wherein the recess is open to the second side in the plate thickness direction, and
the side surface cover is connected to the sealing part.

4. The semiconductor device according to claim 1,
wherein each of the plurality of electrodes has a plate shape spreading in a direction perpendicular to the plate thickness direction.

5. The semiconductor device according to claim 1,
wherein a solder ball is mounted on each of the plurality of electrodes.

6. The semiconductor device according to claim 1, further comprising:
one or more additional side surface cover,
wherein the plurality of electrodes includes a plurality of electrode pairs, and
the side surface cover and one or more additional side surface cover are each connected to a portion between different electrode pairs out of the front surface cover.
